(19) United States
(12) Patent Application Publication
(10) Pub. No.: US 2021/0406654 A1
(43) Pub. Date: Dec. 30, 2021

(54) ARTIFICIAL NEURAL NETWORK WITH SPARSE WEIGHTS

(71) Applicant: Alibaba Group Holding Limited, Georgetown (KY)

(72) Inventors: Fei SUN, San Jose, CA (US); Ao REN, Malden, MA (US)

(21) Appl. No.: 16/914,970

(22) Filed: Jun. 29, 2020

(51) Int. Cl. G06N 3/063; G06N 3/08; G11C 11/34

(52) U.S. Cl. CPC G06N 3/063; G11C 11/34; G06N 3/082

(57) ABSTRACT

The accuracy of multiple stages within an artificial neural network is substantially improved while at the same time utilizing approximately the same number of floating-point operations per second (FLOPS) as prior art neural network stages by filtering the input with large sparse weight matrices and large sparse weight arrays.

### BACKGROUND OF THE INVENTION

### 1. Field of the Invention

The present application relates to the field of artificial neural networks and, in particular, to an artificial neural network with sparse weights.

### 2. Description of the Related Art

An artificial neural network is a computing system originally designed to mimic the human brain where one neuron is connected to many other neurons, and the strengths or weights of the signals transmitted from one neuron to the other neurons vary based on the input such that different weighted signals are sent to different neurons.

Over time, the connections and weights of the signals between neurons change based on a person's learned experience. Supervised machine learning, in turn, is an approach where the artificial neural network trains with a very large number of samples, which is similar to a person's learned experience, and changes the weights of the signals to obtain the desired outcome.

Artificial neural networks are used in many applications, such as natural language processing and image processing. For example, bidirectional encoder representations from transformers (BERT) is a relatively new approach to natural language processing, while a convolutional neural network (CNN) is a well-known approach to image processing. Both approaches typically have a series of identical stages.

FIG. 1A shows a block diagram that illustrates an example of a conventional BERT stage 100. As shown in the FIG. 1A example, BERT stage 100 includes an input circuit 102 that receives an input object IN, and then filters the input object with a forward weight object FWT to generate a first intermediate object FIO.

The input object IN includes a dense (M, K)-sized matrix that has rows and columns of elements that each store a value. Further, the forward weight object FWT includes a dense, locally-stored, (K, P*K)-sized forward weight matrix that has rows and columns of elements that each store a value. In addition, the resulting first intermediate object FIO includes a temporarily-stored (M, P*K)-sized matrix that has rows and columns of elements that each store a value. FIG. 1A illustrates the matrices with M=3 and K=2 for purposes of illustration only. P is a constant multiplier of four in BERT stage 100.

As further shown in FIG. 1A, BERT stage 100 also includes an intermediate circuit 104 that is coupled to input circuit 102, and an output circuit 106 that is coupled to intermediate circuit 104. Intermediate circuit 104 transforms the first intermediate matrix FIO to form a second intermediate matrix SIO, such as by setting all negative values to zero. The second intermediate object SIO includes a temporarily-stored (M, P*K)-sized matrix that has rows and columns of elements that each store a value.

Output circuit 106 receives the second intermediate object SIO and, after this, filters the second intermediate object SIO with a backward weight object BWT to generate an output object OUT. The backward weight object BWT includes a dense, locally-stored, (P*K, K)-sized matrix that has rows and columns of elements that each store a value. The output object OUT includes a temporarily-stored (M, K)-sized matrix that has rows and columns of elements that each store a value. The matrix of the output object OUT is the same size as the matrix of the input object IN.

FIG. 1B shows a block diagram that illustrates an example of a conventional CNN stage 108. As shown in FIG. 1B, CNN stage 108, which is also known as bottleneck residual stage, includes three circuits that are connected in series, and include an input circuit 110, followed by an intermediate circuit 112, followed by an output circuit 114.

Each circuit 110, 112, 114 receives an input cube that has layers of input arrays, and transmits an output cube that has layers of output arrays. The output cube transmitted from one circuit becomes the input cube received by the next circuit. In the FIG. 1B example, the input cube received by input circuit 110 has 24 layers where each layer is a 56×56 array (56×56×24).

Each circuit 110, 112, 114 also has a memory that stores representations of a number of 1×1 and 3×3 weighted cubes, where each weighted cube has layers of arrays, each of which has a number of entries. As a result, each weighted cube has a number of entries, more than half of which are non-zero. The number of layers or the depths of the input and weighted cubes must match. The number of weighted cubes, in turn, defines the number of arrays in the output cube that is generated by the circuit.

In operation, input circuit 110 receives a signal that represents a 56×56×24 cube, expands the number of arrays from 24 to 144 (the increase in the number of arrays is defined by an input factor, which is set to six by default) with 1×1 weighted cubes by multiplying a matrix of size 24×144, and transmits an output signal that represents a 56×56×144 cube. Intermediate circuit 112 receives the output signal that represents the 56×56×144 cube, transforms the cube with the 3×3 weighted cubes, and transmits an output signal that represents a transformed 56×56×144 cube.

Finally, output circuit 114 receives the output signal that represents the transformed 56×56×144 cube, reduces the number of arrays from 144 to 24 with 1×1 weighted cubes by multiplying a matrix of size 144×24, and transmits an output signal that represents a 56×56×24 cube. Each of the circuits 110, 112, and 114 also perform batch normalization and ReLU6 activation (setting all negative values in the arrays to zero) prior to transmitting an output cube.

Input circuit 110 is also known as an expansion circuit due to the increase in the number of layers, while output circuit 114 is also known as a projection circuit due to the decrease in the number of layers. The expansion from 24 arrays to 144 arrays provided by input circuit 110 prior to being transformed by 3×3 intermediate circuit 112 occurs because transforming input cubes with large numbers of arrays, such as 144 arrays, provides substantially more information than transforming input cubes with a smaller number of arrays, such as 24 arrays.

On the other hand, reducing the number of arrays from 144 arrays to 24 arrays provided by output circuit 114 provides better performance. The size of the expansion and reduction in the number of arrays represents a tradeoff between performance (faster with fewer arrays) and quality (better accuracy with more arrays).

One drawback of CNN stage 108, however, is that output circuit 114 mixes different features to reduce the amount of information from 144 arrays to 24 arrays and, as a result, reduces the accuracy. As a result, there is a need for a bottleneck residual stage that improves the accuracy.

### SUMMARY OF THE INVENTION

The present invention includes an artificial neural network with improved accuracy. The artificial neural network includes an input circuit that receives an input object that has a dense array with rows and columns of elements that each store a value. In addition, the input circuit filters the input object with a first weight object that has a sparse array with rows and columns of elements to generate a first intermediate object. The artificial neural network also includes an intermediate circuit that is coupled to the input circuit. The intermediate circuit modifies the first intermediate object to generate a second intermediate object. In addition, the artificial neural network includes an output circuit that filters the second intermediate object with a second weight object that has a sparse array with rows and columns of elements to generate an output object.

The present invention also includes a method of operating an artificial neural network. The method includes receiving an input object that has a dense array with rows and columns of elements that each store a value, and filtering the input object with a first weight object that has a sparse array with rows and columns of elements to generate a first intermediate object. The method also includes modifying the first intermediate object to generate a second intermediate object, and filtering the second intermediate object with a second weight object that has a sparse array with rows and columns of elements to generate an output object.

The present invention additionally provides a non-transitory computer-readable storage medium that has embedded therein program instructions, which when executed by a processor causes the processor to execute a method of operating an artificial neural network. The method includes receiving an input object that has a dense array with rows and columns of elements that each store a value, and filtering the input object with a first weight object that has a sparse array with rows and columns of elements to generate a first intermediate object. The method also includes modifying the first intermediate object to generate a second intermediate object, and filtering the second intermediate object with a second weight object that has a sparse array with rows and columns of elements to generate an output object.

A better understanding of the features and advantages of the present invention will be obtained by reference to the following detailed description and accompanying drawings which set forth an illustrative embodiment in which the principals of the invention are utilized.

### BRIEF DESCRIPTION OF THE DRAWINGS

FIG. 1A is a block diagram illustrating an example of a conventional BERT stage 100.

FIG. 1B is a block diagram illustrating an example of a conventional CNN stage 108.

FIG. 2A is a block diagram illustrating an example of a BERT stage 200 in accordance with the present invention.

FIG. 2B is a block diagram illustrating an example of input circuit 202 in accordance with the present invention.

FIG. 2C is a block diagram illustrating an example of a CNN stage 208 in accordance with the present invention.

FIGS. 3A-3F are a series of views illustrating an example of input circuit 210 to illustrate an example of the operation of input circuit 210 in accordance with the present invention.

FIGS. 4A-4J are a series of views illustrating an example of intermediate circuit 220 to illustrate an example of the operation of depth-wise circuit 220 in accordance with the present invention.

FIG. 5 is a block diagram illustrating an example of output circuit 226 in accordance with the present invention.

FIG. 6 is a block diagram illustrating an example of a CNN 600 in accordance with the present invention.

FIG. 7 is a flow chart illustrating an example of a method 700 of forming a sparse weight cube in accordance with the present invention.

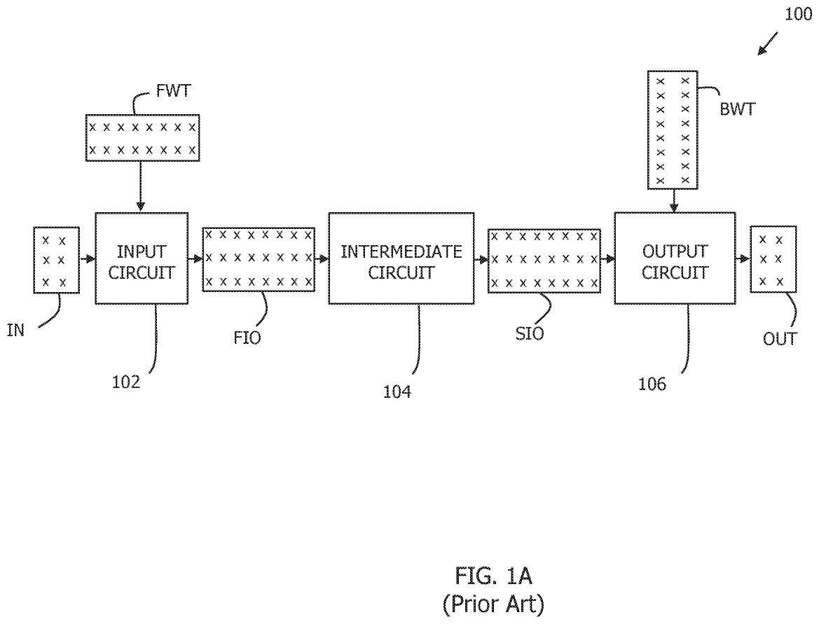

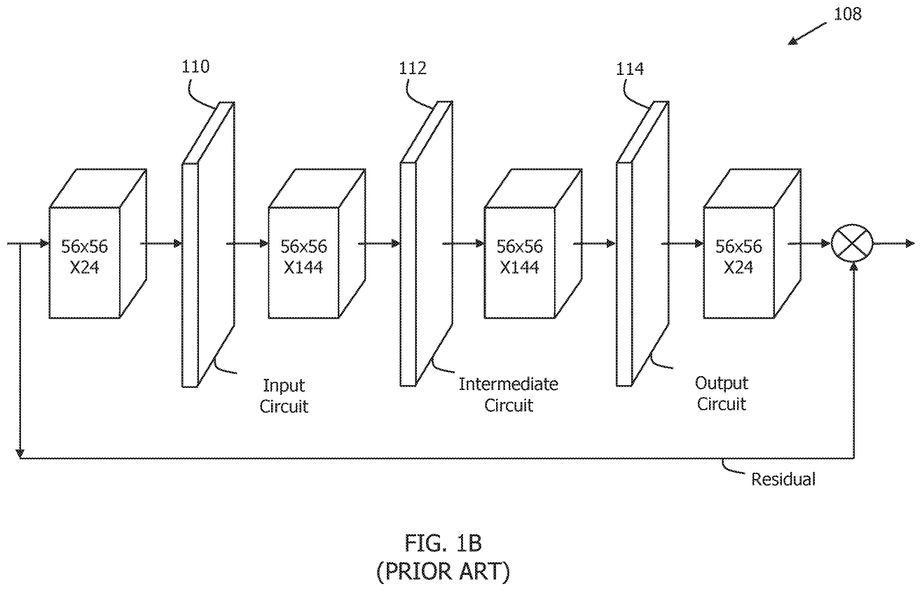

### DETAILED DESCRIPTION OF THE INVENTION

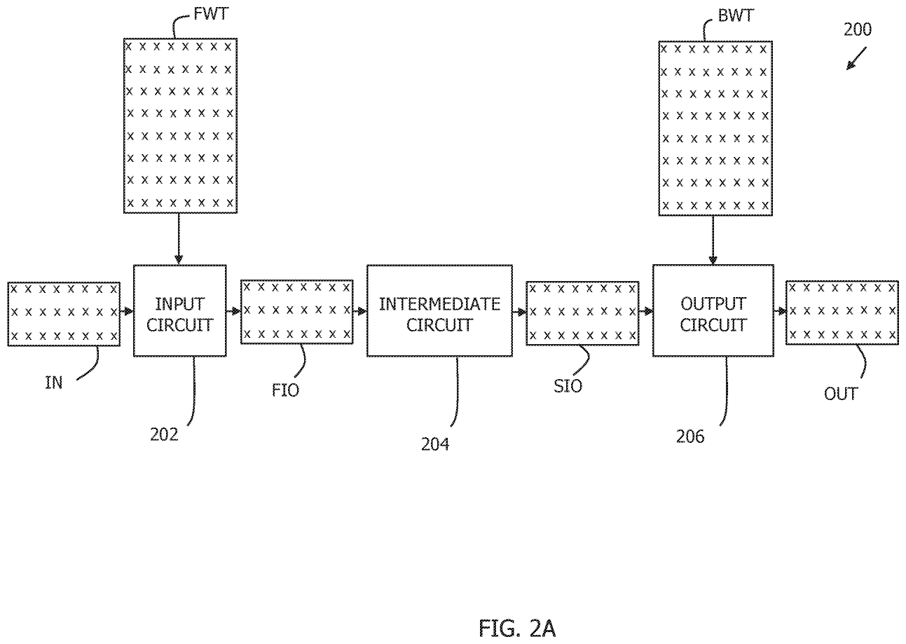

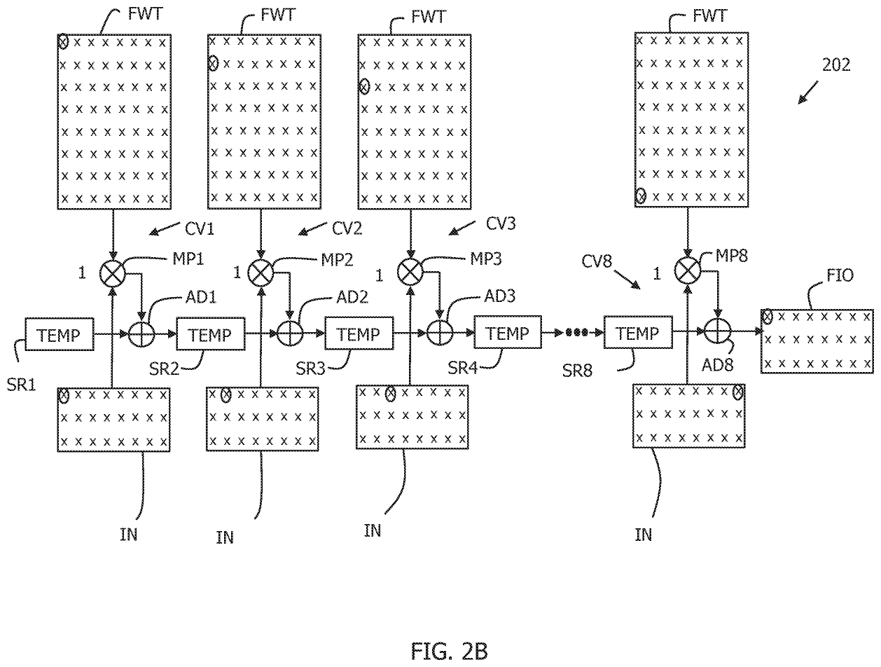

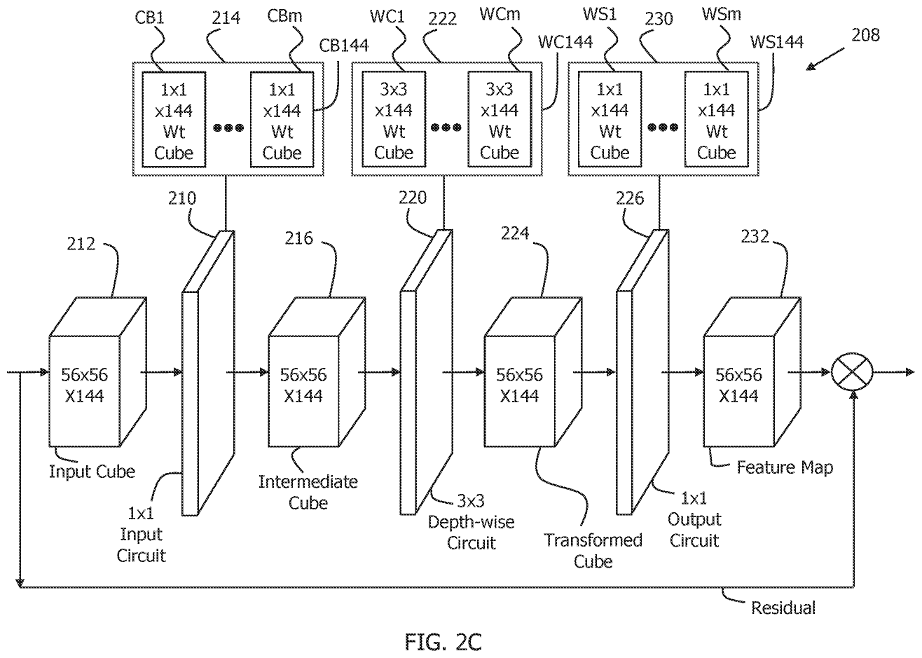

FIG. 2A shows a block diagram that illustrates an example of a BERT stage 200 in accordance with the present invention. As shown in the FIG. 2A example, BERT stage 200 includes an input circuit 202 that receives an input object IN, and then filters the input object with a forward weight object FWT to generate a first intermediate object FIO.

In the present example, the input object IN includes a (M, P*K)-sized matrix that has rows and columns of elements that each store a value. Further, the weight object FWT includes a locally-stored, (P*K, P*K)-sized matrix that has rows and columns of elements that each store a value. In addition, the resulting first intermediate object FIO includes a temporarily-stored, (M, P*K)-sized matrix that has rows and columns of elements that each store a value. FIG. 2A illustrates the matrices with M=3 and K=2 for purposes of illustration only. P is a constant multiplier of four in BERT stage 200.

As further shown in FIG. 2A, BERT stage 200 also includes an intermediate circuit 204 that is coupled to input circuit 202, and an output circuit 206 that is coupled to intermediate circuit 204. Intermediate circuit 204 transforms the first intermediate matrix FIO to form a second intermediate matrix SIO, such as by setting all negative values to zero. In the present example, the second intermediate object SIO includes a temporarily-stored, (M, P*K)-sized matrix that has rows and columns of elements that each store a value.

Output circuit 206 receives the second intermediate object SIO and, after this, filters the second intermediate object SIO with a backward weight object BWT to generate an output object OUT that has the same size as the original input object IN. In the present example, the backward weight object includes a locally-stored, (P*K, P*K)-sized matrix that has rows and columns of elements that each store a value. The output object OUT includes a temporarily-stored, (M, P*K)-sized matrix that has rows and columns of elements that each store a value.

In accordance with the present invention, the matrix of the input object IN is a dense matrix (i.e., more than half of the entries in the matrix are non-zero), whereas the matrix of the forward weight object FWT is a sparse matrix (i.e., more than half of the entries in the matrix are zero). Similarly, the matrix of the backward weight object BWT is a sparse matrix. Alternately, the matrices of the forward weight object FWT and the backward weight object BWT can be super sparse (i.e., 80%+ of the entries are zero).

FIG. 2B shows a block diagram that illustrates an example of input circuit 202 in accordance with the present invention. In the FIG. 2B example, input circuit 202 includes eight internal circuits CV1-CV8 that are coupled to the sparse matrix of the forward weight object FWT. The internal circuits CV1-CV8, in turn, include eight multipliers MP1-MP8 that are coupled to the sparse matrix of the forward weight object FWT, eight adders AD1-AD8 that are coupled to the multipliers MP1-MP8, and eight temporary storage registers SR1-SR8 that are coupled to the adders AD1-AD8.

In operation, as shown in FIG. 2B, input circuit 202 first determines the value to be stored in element 1,1 of the matrix of the first intermediate object FIO. The determination begins with multiplier MP1 multiplying the value stored in element 1,1 of the dense matrix of the input object IN, and the weight value stored in element 1,1 of the matrix of the forward weight object FWT to generate a result. Adder AD1 then adds the result to an initial value stored in temporary storage register SR1 to generate a first temporary value that is stored in temporary storage register SR2.

Next, multiplier MP2 multiplies the value stored in element 1,2 of the matrix of the input object IN, and the weight value stored in element 2,1 to generate a result. Adder AD2 then adds the result to the temporary value stored in register SR2 to generate a temporary value that is stored in temporary storage register SR3. Following this, multiplier MP3 multiplies the value stored in element 1,3 of the matrix of input object IN, and the weight value stored in element 3,1 to generate a result. Adder AD3 then adds the result to the temporary value stored in register SR3 to generate a temporary value that is stored in temporary storage register SR4.

Circuit 210 continues as above, ending with multiplier MP8 multiplying the value stored in element 1,8 of the matrix of input object IN, and the weight value stored in element 8,1 of the matrix of the forward weight object FWT to generate a result. Adder AD144 then adds the result to the temporary value stored in register SR144 to generate a final value that is stored in element 1,1 of the matrix of the first intermediate object FIO.

In addition, output circuit 206 is structurally and operationally substantially the same as input circuit 202, except that output circuit 206 utilizes a backward weight object BWT in lieu of the forward weight object FWT of circuit 202.

One of the advantages of the present invention is that utilizing sparse weight matrices, forward FWT and backward BWT, allows much larger weight matrices to be used while consuming approximately the same number of floating-point operations per second (FLOPS). Much larger weight matrices, in turn, provide substantially greater accuracy.

FIG. 2C shows a block diagram that illustrates an example of a CNN stage 208 in accordance with the present invention. As shown in the FIG. 2C example, CNN stage 208 includes an input circuit 210 that receives an input object, and then filters the input object with a forward weight object to generate a first intermediate object.

In the FIG. 2C example, the input object includes a number of arrays, which are known as channel arrays, that are arranged as an input cube 212. In other words, input circuit 210 receives input cube 212 which has a number of channel arrays where each channel array is a layer in input cube 212. In addition, each channel array has rows and columns of elements that each store a value. In the FIG. 2C example, input cube 212 has 144—56×56 channel arrays.

Further, input circuit 210 also has a memory 214 that stores a number of sparse input weight cubes CB1-CBm. Each sparse input weight cube CB, in turn, has a number of input weight arrays where the input weight arrays in a sparse input weight cube CB are the layers of the sparse input weight cube CB.

Each input weight array in an input weight cube CB has one element. In the FIG. 2C example, there are 144—1×1 input weight arrays in each sparse input weight cube CB. The element in an input weight array stores a value. As a result, each sparse input weight cube CB has a number of stored values. In the present invention, more than half of the stored values in a sparse input weight cube CB are zero.

In operation, circuit 210 filters input cube 212 with the sparse input weight cubes CB1-CBm to generate an intermediate cube 216 that has a number of intermediate arrays where each intermediate array is a layer in intermediate cube 216. In addition, each intermediate array has rows and columns of elements that store a value. In the FIG. 2C example, intermediate cube 216 has 144—56×56 intermediate arrays.

As shown in FIG. 2C, CNN stage 200 further includes an intermediate circuit 220 that transforms intermediate cube 216 to generate a transformed cube 224. Intermediate circuit 220 has a memory 222 that stores a number of dense weight cubes WC1-WCm. Each dense weight cube WC has a number of dense weight arrays where the dense weight arrays in a dense weight cube WC are the layers of the dense weight cube WC.

In addition, each dense weight array has rows and columns of elements that store a value. In the present invention, less than one half of the stored values in a dense weight array are zero, while less than one half of the stored values in a dense weight cube WC are zero. In the FIG. 2C example, there are 144—3×3 dense weight arrays where each dense weight array is a layer in a dense weight cube WC.

In the present example, intermediate circuit 220 transforms intermediate cube 216 with a 3×3 depth-wise convolution. In operation, intermediate circuit 220 transforms intermediate cube 216 with the dense weight cubes WC1-WCm to generate a transformed cube 224 that has a number of transformed arrays where each transformed array is a layer in transformed cube 224. In addition, each transformed array has rows and columns of elements that store a value. In the FIG. 2C example, transformed cube 224 has 144—56×56 transformed arrays.

As further shown in FIG. 2C, CNN stage 200 further includes an output circuit 226 that has a memory 230 that stores a number of sparse output weight cubes WS1-WSm. Each sparse output weight cube WS, in turn, has a number of output weight arrays where the output weight arrays in a sparse output weight cube WS are the layers of the sparse output weight cube WS.

In addition, each output weight array in a sparse output weight cube WS has one element. In the FIG. 2C example, there are 144—1×1 output weight arrays in each sparse output weight cube WS. The element in an output weight array stores a value. As a result, each sparse output weight cube WS has a number of stored values. In the present invention, more than one half of the stored values in a sparse output weight cube WS are zero, and 80%+ of stored values are zero in a super sparse output weight cube WS.

In operation, circuit 226 filters transformed cube 224 with the sparse output weight cubes WS1-WSm to generate a feature cube 232. A feature cube 232 has a number of feature map arrays where each feature map array is a layer in feature cube 232. In addition, each feature map array has rows and columns of elements that store a value. In the FIG. 2C example, feature cube 232 has 144—56×56 feature map arrays where each feature map array is a layer in feature cube 232. In addition, each of the circuits 210, 220, and 226 also perform batch normalization and ReLU6 activation (setting all negative values in the arrays to zero) prior to outputting a cube.

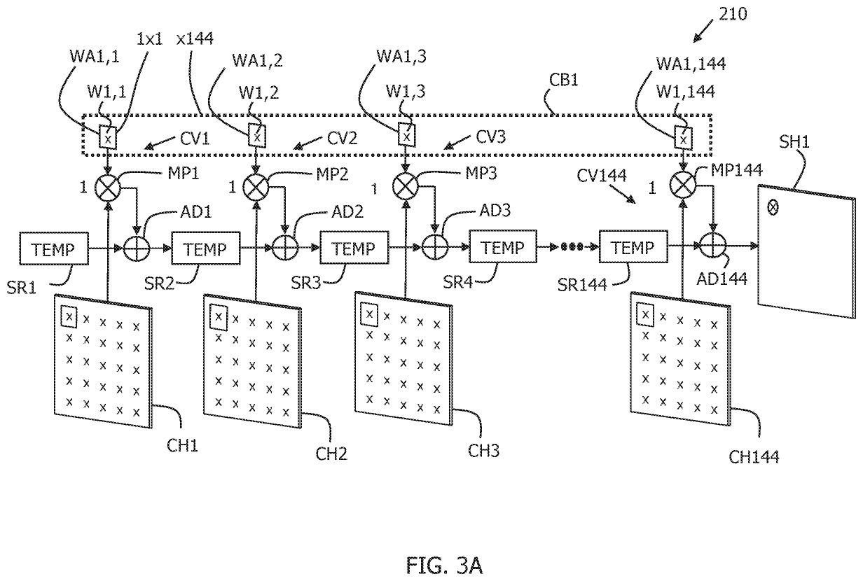

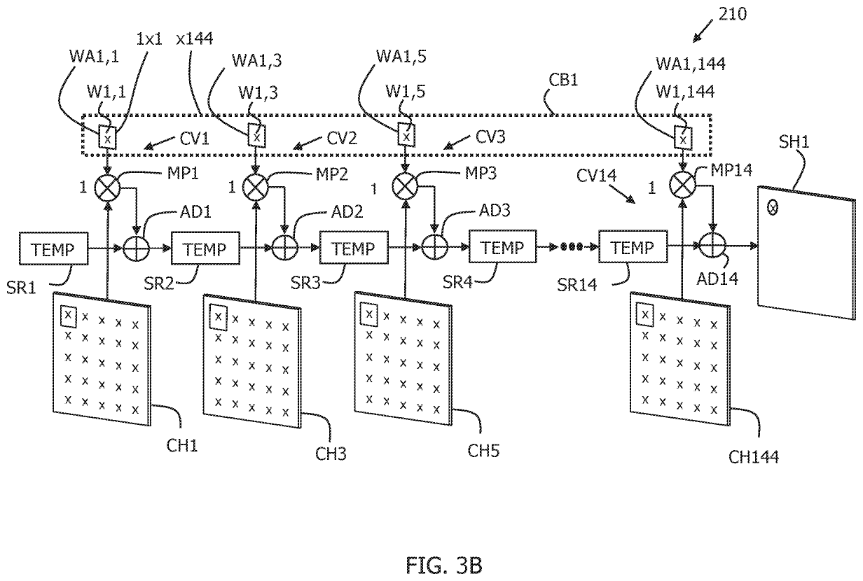

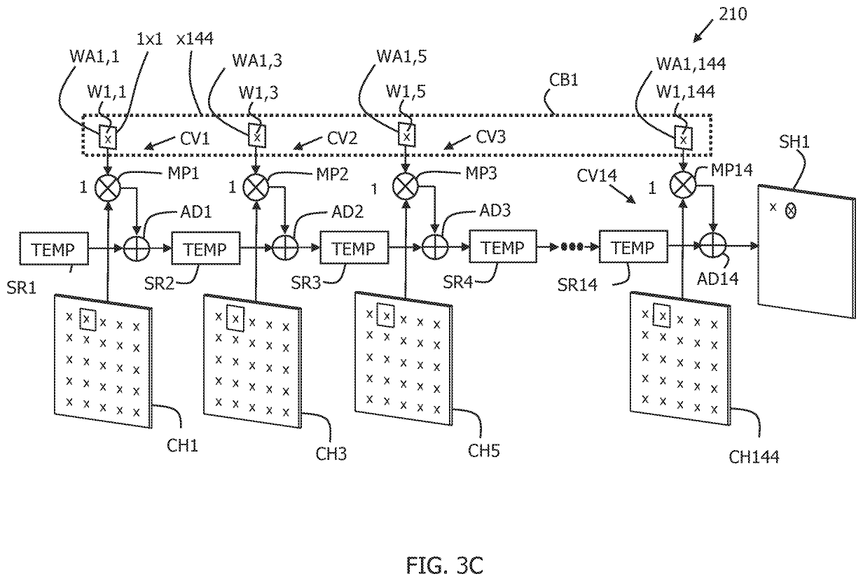

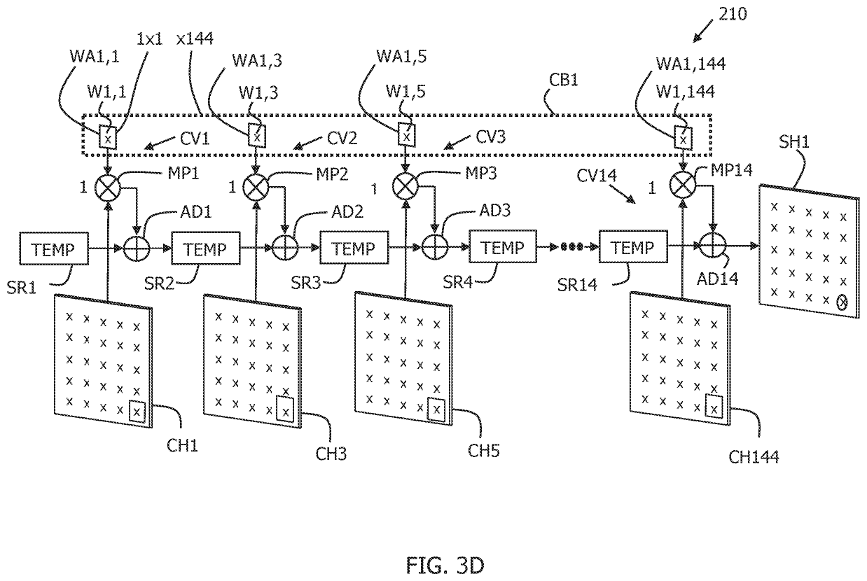

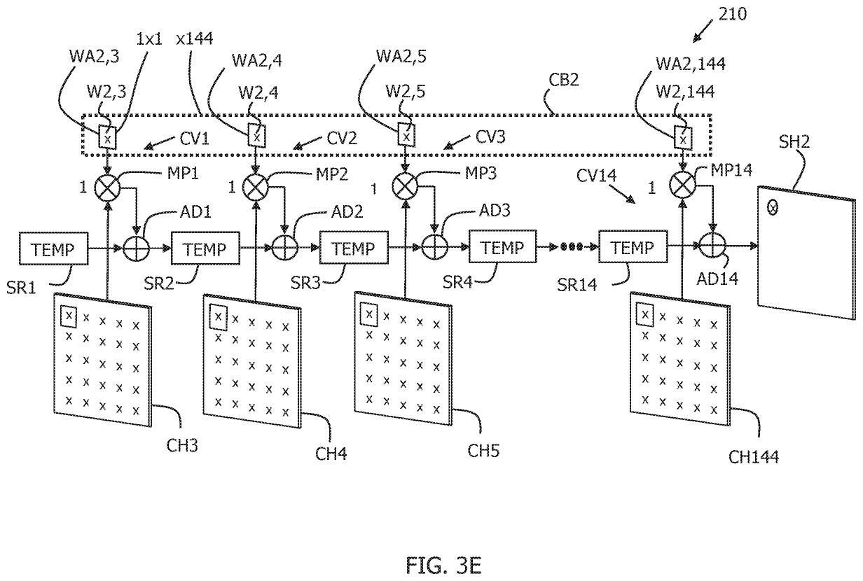

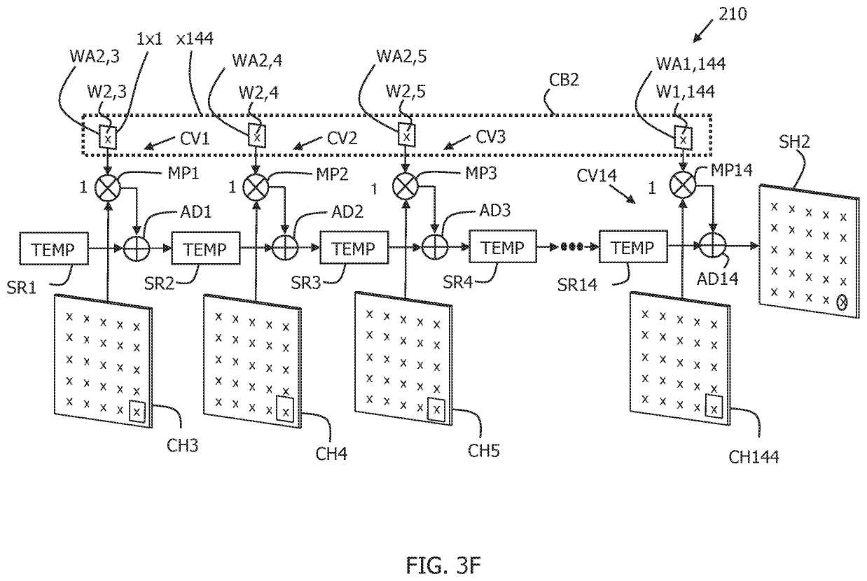

FIGS. 3A-3F show a series of views that illustrate an example of input circuit 210 to illustrate an example of the operation of input circuit 210 in accordance with the present invention. In the FIGS. 3A-3F example, input circuit 210 includes 144 1×1 sparse input weight cubes CB1-CB144, and 144 internal circuits CV1-CV144 that are coupled to the sparse input weight cubes CB1-CB144. The internal circuits CV1-CV144, in turn, include 144 multipliers MP1-MP144 that are coupled to the sparse input weight cubes CB1-CB144, 144 adders AD1-AD144 that are coupled to the multipliers MP1-MP144, and 144 temporary storage registers SR1-SR144 that are coupled to the adders AD1-AD144.

In a first operation, as shown in FIG. 3A, input circuit 210 first determines the value to be stored in element 1,1 of an intermediate array SH1 of an intermediate cube, such as intermediate cube 216. The determination begins with multiplier MP1 multiplying the value stored in element 1,1 of a channel array CH1 of an input cube, such as input cube 212, and the weight value W1,1 stored in a 1×1 weight array WA1,1 of sparse input weight cube CB1 to generate a result. Adder AD1 then adds the result to an initial value stored in temporary storage register SR1 to generate a first temporary value that is stored in temporary storage register SR2.

Next, multiplier MP2 multiplies the value stored in element 1,1 of channel array CH2 of the input cube, and the weight value W1,2 stored in a 1×1 weight array WA1,2 of sparse input weight cube CB1 to generate a result. Adder AD2 then adds the result to the temporary value stored in register SR2 to generate a temporary value that is stored in temporary storage register SR3. Following this, multiplier MP3 multiplies the value stored in element 1,1 of channel array CH3, and the weight value W1,3 stored in a 1×1 weight array WA1,3 of sparse input weight cube CB1 to generate a result. Adder AD3 then adds the result to the temporary value stored in register SR3 to generate a temporary value that is stored in temporary storage register SR4.

Circuit 210 continues as above, ending with multiplier MP144 multiplying the value stored in element 1,1 of channel array CH144, and the weight value W1,144 stored in a 1×1 weight array WA1,144 of sparse input weight cube CB1 to generate a result. Adder AD144 then adds the result to the temporary value stored in register SR144 to generate a final value that is stored in element 1,1 of intermediate array SH1.

In a second operation, the sparse input weight cube CB1 can be stored in an efficient manner using a compression format such as compressed sparse row format (CSR), block compressed row format (BSR), and compressed sparse column format (CSC). In these formats, only the non-zero values are stored along with row, column, and value information. As a result, multiplication is performed on only the non-zero values, which results in a significant savings in resources such as memory and power.

For example, if the first five values of sparse input weight cube CB1 are 1-0-1-0-1, the last value is 1, and the total number of values is 14, then, as shown in FIG. 3B, the determination begins with multiplier MP1 multiplying the value stored in element 1,1 of a channel array CH1 of an input cube, such as input cube 212, and the weight value W1,1 stored in a 1×1 weight array WA1,1 of sparse input weight cube CB1 to generate a result. Adder AD1 then adds the result to an initial value stored in temporary storage register SR1 to generate a first temporary value that is stored in temporary storage register SR2.

Next, multiplier MP2 multiplies the value stored in element 1,1 of channel array CH3 of the input cube, and the weight value W1,3 stored in a 1×1 weight array WA1,3 of sparse input weight cube CB1 to generate a result. Adder AD2 then adds the result to the temporary value stored in register SR2 to generate a temporary value that is stored in temporary storage register SR3.

Following this, multiplier MP3 multiplies the value stored in element 1,1 of channel array CH5, and the weight value W1,5 stored in a 1×1 weight array WA1,5 of sparse input weight cube CB1 to generate a result. Adder AD3 then adds the result to the temporary value stored in register SR3 to generate a temporary value that is stored in temporary storage register SR4.

Circuit 210 continues as above, ending with multiplier MP14 multiplying the value stored in element 1,1 of channel array CH144, and the weight value W1,144 stored in a 1×1 weight array WA1,144 of sparse input weight cube CB1 to generate a result. Adder AD14 then adds the result to the temporary value stored in register SR14 to generate a final value that is stored in element 1,1 of intermediate array SH1.

Next, as shown in FIG. 3C, circuit 300 determines the value to be stored in element 1,2 of intermediate array SH1. The determination begins with multiplier MP1 multiplying the value stored in element 1,2 of channel array CH1 and the value of weight W1,1 to generate a result. Adder AD1 then adds the result to an initial value stored in temporary storage register SR1 to generate a temporary value that is stored in temporary storage register SR2.

Next, multiplier MP2 multiplies the value of element 1,2 of channel array CH3 and the value of weight W1,3 to generate a result. Adder AD2 then adds the result to the temporary value stored in register SR2 to generate a temporary value that is stored in temporary storage register SR3. Following this, multiplier MP3 multiplies the value of element 1,2 of channel array CH5 and the value of weight W1,5 to generate a result. Adder AD3 then adds the result to the temporary value stored in register SR3 to generate a temporary value that is stored in temporary storage register SR4.

Input circuit 210 continues as above, ending with multiplier MP14 multiplying the value of element 1,2 of channel array CH144 and the weight value W1,144 to generate a result. Adder AD14 then adds the result to the temporary value stored in register SR14 to generate a final value that is stored in element 1,2 of intermediate array SH1.

Circuit 210 continues as above until, as shown in FIG. 3D, the value of element 5,5 of intermediate array SH1 of the intermediate cube has been determined and stored. Once the value of element 5,5 of intermediate array SH1 has been determined and stored, circuit 210 moves to determine the values for the elements of an intermediate array SH2 of the intermediate cube.

As shown in FIG. 3E, input circuit 210 next determines the value of element 1,1 of intermediate array SH2. Continuing with the above example, if the first five values of sparse input weight cube CB2 are 0-0-1-1-1, the last value is 1, and the total number of values is 14, then, as shown in FIG. 3E, the determination begins with multiplier MP1 multiplying the value stored in element 1,1 of a channel array CH3 of an input cube, such as input cube 212, and the weight value W2,3 stored in a 1×1 weight array WA2,3 of sparse input weight cube CB2 to generate a result. Adder AD1 then adds the result to an initial value stored in temporary storage register SR1 to generate a first temporary value that is stored in temporary storage register SR2.

Next, multiplier MP2 multiplies the value of element 1,1 of channel array CH4 and the weight value W2,4 stored in a 1×1 weight array WA2,4 of sparse input weight cube CB2 to generate a result. Adder AD2 then adds the result to the temporary value stored in register SR2 to generate a temporary value that is stored in temporary storage register SR3. Following this, multiplier MP3 multiplies the value of element 1,1 of channel array CH5 and the weight value W2,5 stored in a 1×1 weight array WA2,5 of a sparse input weight cube CB2 to generate a result. Adder AD3 then adds the result to the temporary value stored in register SR3 to generate a temporary value that is stored in temporary storage register SR4.

Input circuit 210 continues as above, ending with multiplier MP14 multiplying the value of element 1,1 of channel array CH144 and the weight value W2,144 to generate a result. Adder AD144 then adds the result to the temporary value stored in register SR144 to generate a final value that is stored in element 1,1 of intermediate array SH2 of the intermediate cube.

Circuit 210 continues as above until, as shown in FIG. 3F, the value of element 5,5 of intermediate array SH2 of the intermediate cube has been determined and stored. Once the value of element 5,5 of intermediate array SH2 has been determined and stored, circuit 210 continues as above until the values for all of the elements of all of the remaining intermediate arrays SH3-SH144 have been determined and stored. The result is an intermediate cube with 144-5×5 feature maps. The channel arrays are illustrated as 5×5 arrays rather than 56×56 arrays for simplicity. Using 56×56 arrays generates a 56×56×144 intermediate cube 216 as shown in FIG. 2.

The weights required for the sparse input weight cubes and arrays can be represented in an input weight table as shown in TABLE 1, which illustrates 144—1×1×144 sparse input weight cubes.

TABLE 1

| | Input CH1 | Input CH2 | Input CH3 | Input CH144 |
|---|---|---|---|---|
| In Wt Cube CB1 | W1, 1 | W1, 2 | W1, 3 | W1, 144 |
| In Wt Cube CB2 | W2, 1 | W2, 2 | W2, 3 | W2, 144 |
| In Wt Cube CB3 | W3, 1 | W3, 2 | W3, 3 | W3, 144 |
| In Wt Cube CB144 | W144, 1 | W144, 2 | W144, 3 | W144, 144 |

In the present invention, the input weight table in TABLE 1 is a sparse table, which is a table where the number of zero entries is more than one-half of the total entries in the table. The input weight table can alternately be a super sparse table where 80%+ of the values are zero. A dense table, on the other hand, is a table where the number of zero entries is less than one-half of the total entries. One advantage of the present invention is that sparse and super sparse weight tables substantially reduce the number of required computations by avoiding computing the zero values.

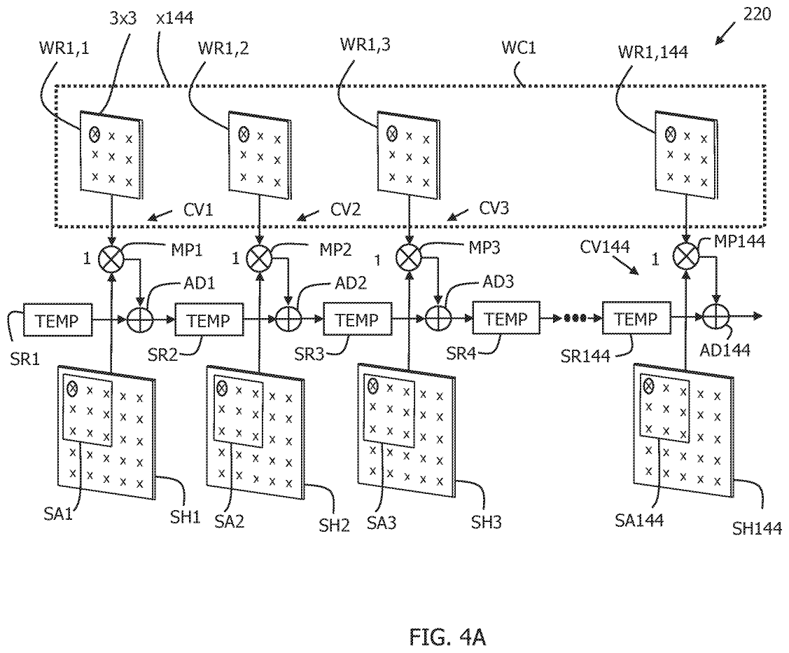

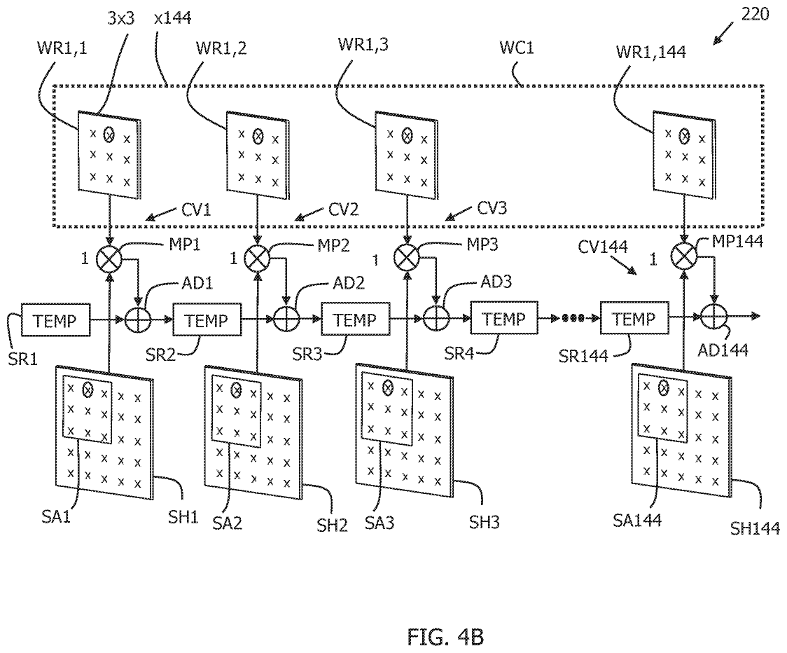

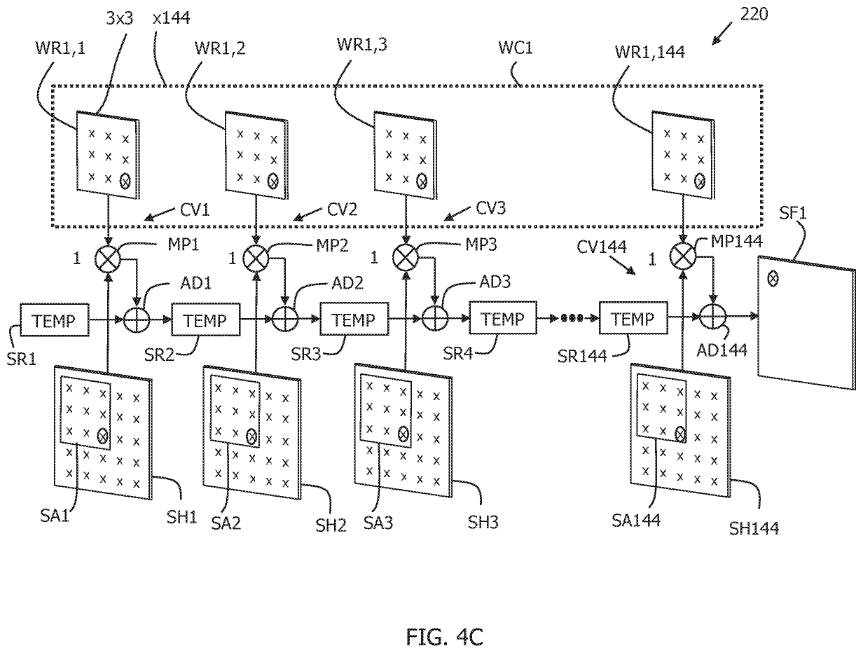

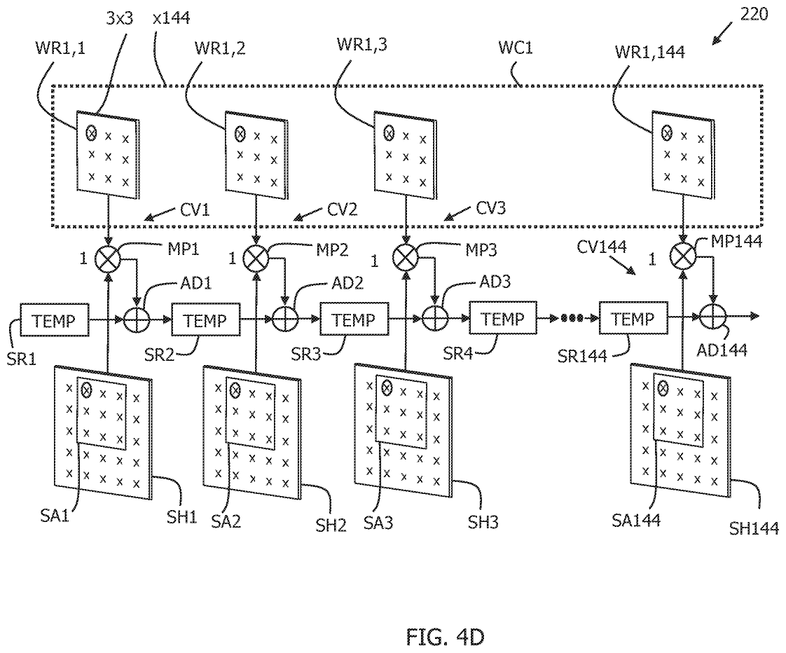

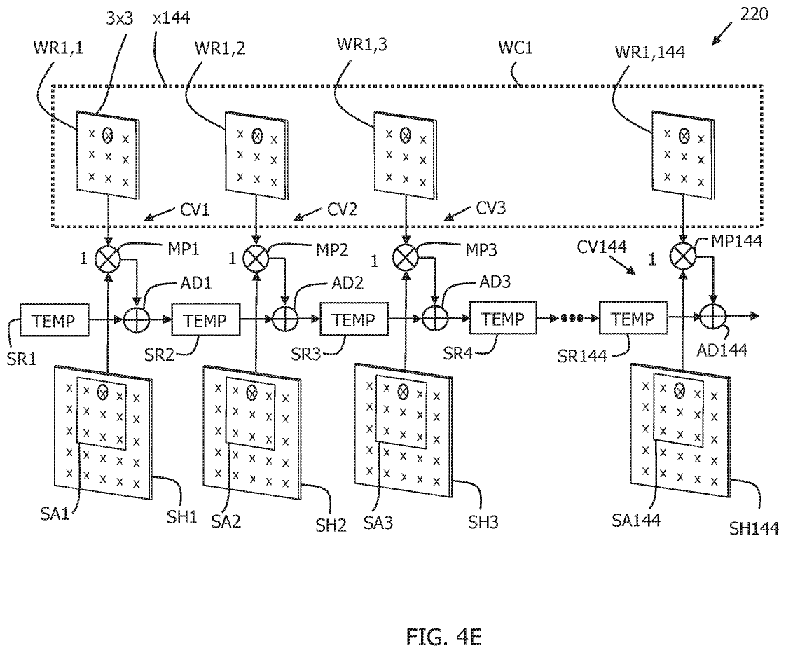

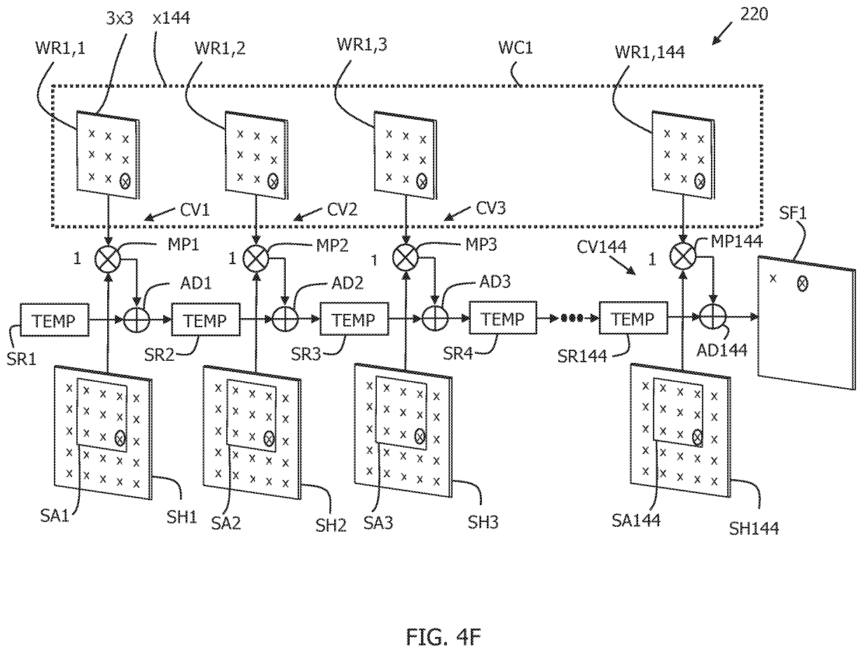

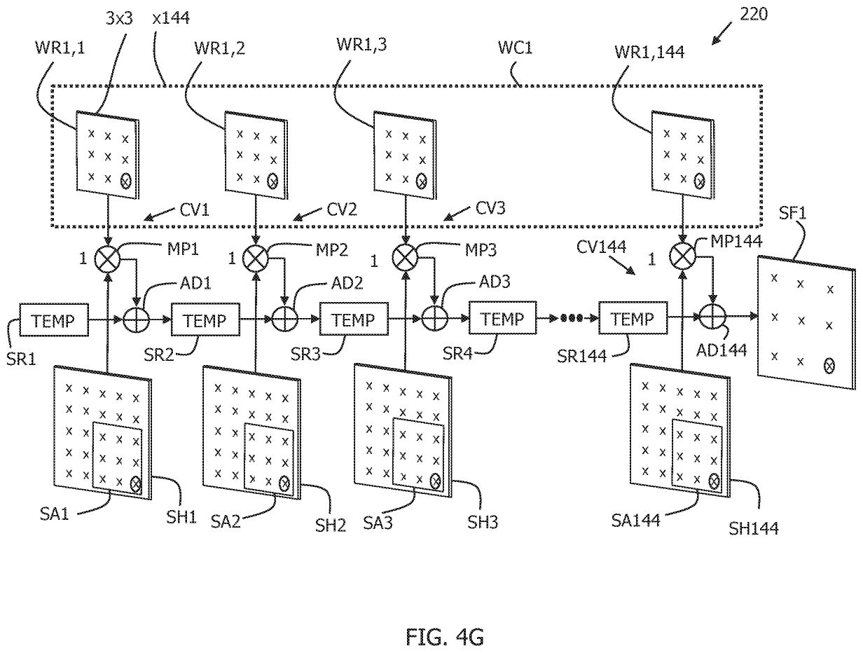

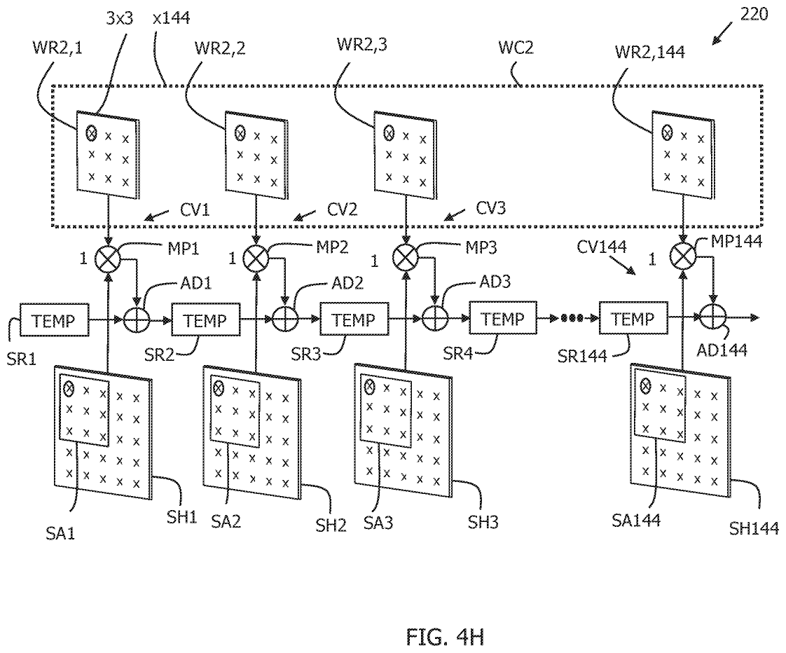

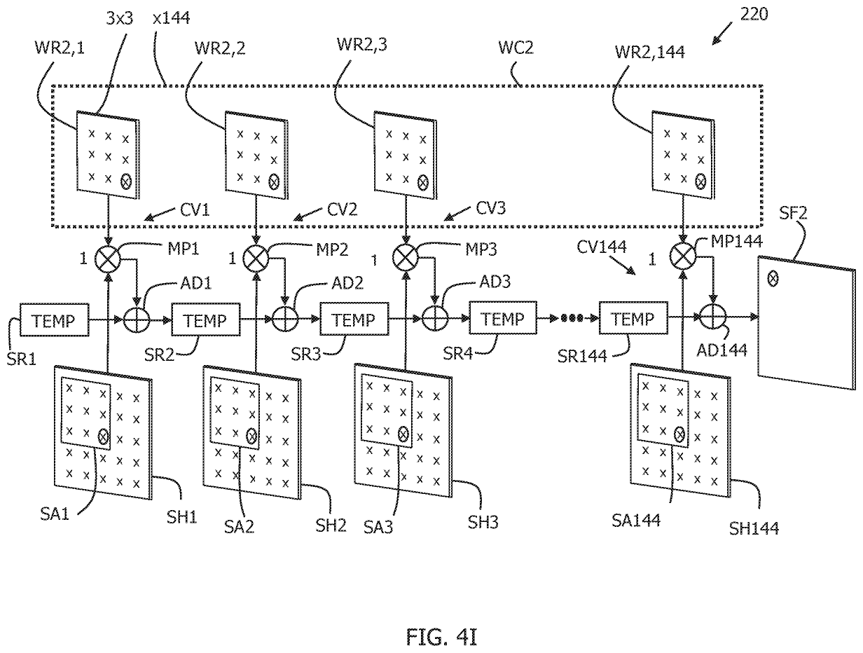

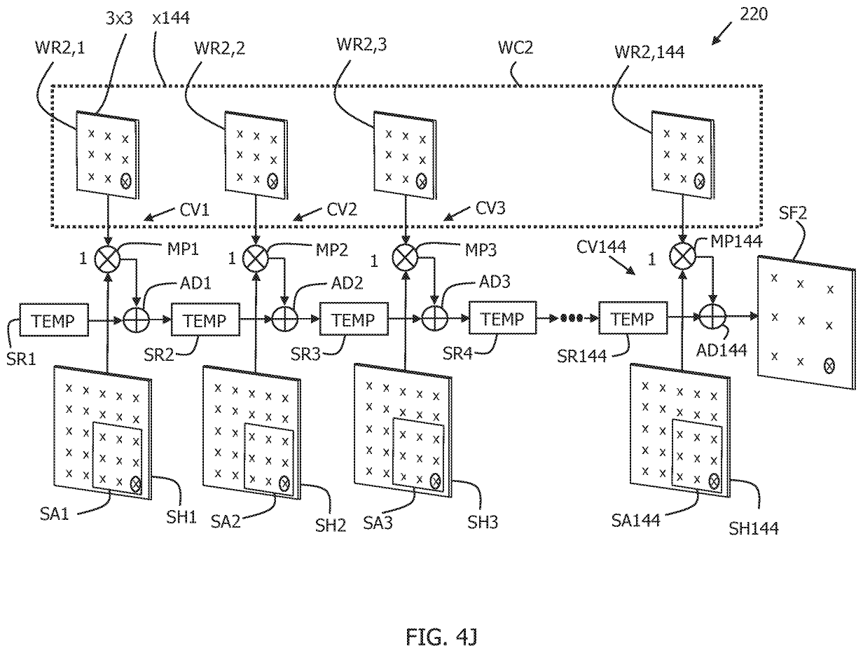

FIGS. 4A-4J show a series of views that illustrate an example of depth-wise circuit 220 to illustrate an example of the operation of depth-wise circuit 220 in accordance with the present invention. Depth-wise circuit 220 is similar to input circuit 210 and, as a result, utilizes the same reference numerals to designate the structures that are common to both circuits.

In operation, as shown in FIG. 4A, depth-wise circuit 220 first determines the value to be stored in element 1,1 of a transformed array SF1 (FIGS. 4C, 4F, and 4G) of a transformed cube, such as transformed cube 224. The determination begins with multiplier MP1 multiplying the value stored in element 1,1 of a 3×3 shift array SA1 within an intermediate array SH1 of an intermediate cube, such as intermediate cube 216, and the weight value stored in element 1,1 of a 3×3 dense weight array WR1,1 of a dense weight cube WC1 to generate a result. Adder AD1 then adds the result to an initial value stored in temporary storage register SR1 to generate a first temporary value that is stored in temporary storage register SR2.

Next, multiplier MP2 multiplies the value stored in element 1,1 of a 3×3 shift array SA2 within an intermediate array SH2 of the intermediate cube, and the weight value stored in element 1,1 of a 3×3 dense weight array WR1,2 of dense weight cube WC1 to generate a result. Adder AD2 then adds the result to the temporary value stored in register SR2 to generate a temporary value that is stored in temporary storage register SR3. Following this, multiplier MP3 multiplies the value stored in element 1,1 of a 3×3 shift array SA3 within an intermediate array SH3, and the weight value stored in element 1,1 of a 3×3 dense weight array WR1,3 of dense weight cube CB1 to generate a result. Adder AD3 then adds the result to the temporary value stored in register SR3 to generate a temporary value that is stored in temporary storage register SR4.

Depth-wise circuit 220 continues as above, ending with multiplier MP144 multiplying the value stored in element 1,1 of a 3×3 shift array SA144 within intermediate array SH144, and the weight value stored in element 1,1 of a 3×3 dense weight array WR1,144 of dense weight cube WC1 to generate a result. Adder AD144 then adds the result to the temporary value stored in register SR144 to generate a value that is stored in temporary register SR1 as an element 1,1 value.

As shown in FIG. 4B, multiplier MP1 next multiplies the value stored in element 1,2 of 3×3 shift array SA1 within intermediate array SH1, and the weight value stored in element 1,2 of 3×3 weight array WR1,1 of weight cube WC1 to generate a result. Adder AD1 then adds the result to the element 1,1 value stored in temporary storage register SR1 to generate a temporary value that is stored in temporary storage register SR2.

Following this, multiplier MP2 multiplies the value stored in element 1,2 of 3×3 shift array SA2 within intermediate array SH2, and the weight value stored in element 1,2 of 3×3 weight array WR1,2 of weight cube WC1 to generate a result. Adder AD2 then adds the result to the temporary value stored in register SR2 to generate a temporary value that is stored in temporary storage register SR3. Next, multiplier MP3 multiplies the value stored in element 1,2 of 3×3 shift array SA3 within intermediate array SH3, and the weight value stored in element 1,2 of 3×3 weight array WR1,3 of weight cube WC1 to generate a result. Adder AD3 then adds the result to the temporary value stored in register SR3 to generate a temporary value that is stored in temporary storage register SR4.

Circuit 220 continues as above, ending with multiplier MP144 multiplying the value stored in element 1,2 of 3×3 shift array SA144 within intermediate array SH144, and the weight value stored in element 1,2 of 3×3 weight array WR1,144 of weight cube CB1 to generate a result. Adder AD144 then adds the result to the temporary value stored in register SR144 to generate a value that is stored in temporary register SR1 as an element 1,2 value.

Circuit 220 continues as above ending, as shown in FIG. 4C, with multiplier MP144 multiplying the value stored in element 3,3 of 3×3 shift array SA144 within intermediate array SH144, and the weight value stored in element 3,3 of 3×3 weight array WR1,144 of weight cube WC1 to generate a result. Adder AD144 then adds the result to the temporary value stored in temporary storage register SR144 to generate a final value that is stored in element 1,1 of transformed array SF1 of the transformed cube. Once the value of element 1,1 of transformed array SF1 has been determined and stored, circuit 220 continues by determining the value of element 1,2 of transformed array SF1 of the transformed cube.

As shown in FIG. 4D, the determination begins with circuit 220 shifting each of the shift arrays SA1-SA144 one stride to the right. After this, multiplier MP1 multiplies the value stored in element 1,1 of a shifted 3×3 shift array SA1 within intermediate array SH1, and the weight value stored in element 1,1 of 3×3 weight array WR1,1 of weight cube WC1 to generate a result. Adder AD1 then adds the result to an initial value stored in temporary storage register SR1 to generate a temporary value that is stored in temporary storage register SR2.

Next, multiplier MP2 multiplies the value stored in element 1,1 of a shifted 3×3 shift array SA2 within intermediate array SH2, and the weight value stored in element 1,1 of 3×3 weight array WR1,2 of weight cube WC1 to generate a result. Adder AD2 then adds the result to the temporary value stored in register SR2 to generate a temporary value that is stored in temporary storage register SR3. Following this, multiplier MP3 multiplies the value stored in element 1,1 of a shifted 3×3 shift array SA3 within intermediate array SH3, and the weight value stored in element 1,1 of 3×3 weight array WR1,3 of weight cube WC1 to generate a result. Adder AD3 then adds the result to the temporary value stored in register SR3 to generate a temporary value that is stored in temporary storage register SR4.

Circuit 220 continues as above, ending with multiplier MP144 multiplying the value stored in element 1,1 of a shifted 3×3 shift array SA144 within intermediate array SH144, and the weight value stored in element 1,1 of 3×3 weight array WR1,144 of weight cube WC1 to generate a result. Adder AD144 then adds the result to the temporary value stored in register SR144 to generate a value that is stored in temporary register SR1 as an element 1,1 value.

As shown in FIG. 4E, multiplier MP1 next multiplies the value stored in element 1,2 of 3×3 shift array SA1 within intermediate array SH1, and the weight value stored in element 1,2 of 3×3 weight array WR1,1 of weight cube WC1 to generate a result. Adder AD1 then adds the result to the element 1,1 value stored in temporary storage register SR1 to generate a temporary value that is stored in temporary storage register SR2.

Following this, multiplier MP2 multiplies the value stored in element 1,2 of 3×3 shift array SA2 within intermediate array SH2, and the weight value stored in element 1,2 of 3×3 weight array WR1,2 of weight cube WC1 to generate a result. Adder AD2 then adds the result to the temporary value stored in register SR2 to generate a temporary value that is stored in temporary storage register SR3. Following this, multiplier MP3 multiplies the value stored in element 1,2 of 3×3 shift array SA3 within intermediate array SH3, and the weight value stored in element 1,2 of 3×3 weight array WR1,3 of weight cube WC1 to generate a result. Adder AD3 then adds the result to the temporary value stored in register SR3 to generate a temporary value that is stored in temporary storage register SR4.

Circuit 220 continues as above, ending with multiplier MP144 multiplying the value stored in element 1,2 of 3×3 shift array SA144 within intermediate array SH144, and the weight value stored in element 1,2 of 3×3 weight array WR1,144 of weight cube WC1 to generate a result. Adder AD144 then adds the result to the temporary value stored in register SR144 to generate a value that is stored in temporary register SR1 as an element 1,2 value.

Circuit 220 continues as above ending, as shown in FIG. 4F, with multiplier MP144 multiplying the value stored in element 3,3 of 3×3 shift array SA144 within intermediate array SH144, and the weight value stored in element 3,3 of 3×3 weight array WR1,144 of weight cube WC1 to generate a result. Adder AD144 then adds the result to the temporary value stored in register SR144 to generate a final value that is stored in element 1,2 of transformed array SF1 of the transformed cube.

Once the value of element 1,2 of transformed array SF1 has been determined and stored, circuit 220 continues as above to determine the elements, ending, as shown in FIG. 4G, with multiplier MP144 multiplying the value stored in element 3,3 of 3×3 shift array SA144 within intermediate array SH144, and the weight value stored in element 3,3 of 3×3 weight array WR1,144 of weight cube WC1 to generate a result. Adder AD144 then adds the result to the temporary value stored in register SR144 to generate a value that is stored in element 3,3 of transformed array SF1 of the transformed cube.

Although transformed array SF1 is shown as a 3×3 array, a 5×5 array can be formed by padding the arrays (using a 7×7 input array made by adding zeros around the periphery of a 5×5 input array to generate a 5×5 output array). Once the value of element 3,3 of transformed array SF1 has been determined and stored, circuit 2102 determines the values for the elements of a transformed array SF2 of the transformed cube.

As shown in FIG. 4H, the determination begins with multiplier MP1 multiplying the value stored in element 1,1 of 3×3 shift array SA1 within intermediate array SH1, and the weight value stored in element 1,1 of 3×3 weight array WR2,1 of weight cube WC2 to generate a result. Adder AD1 then adds the result to an initial value stored in temporary storage register SR1 to generate a temporary value that is stored in temporary storage register SR2.

Next, multiplier MP2 multiplies the value stored in element 1,1 of 3×3 shift array SA2 within intermediate array SH2, and the weight value stored in element 1,1 of 3×3 weight array WR2,2 of weight cube WC2 to generate a result. Adder AD2 then adds the result to the temporary value stored in register SR2 to generate a temporary value that is stored in temporary storage register SR3. Following this, multiplier MP3 multiplies the value stored in element 1,1 of 3×3 shift array SA3 within intermediate array SH3, and the weight value stored in element 1,1 of 3×3 weight array WR2,3 of weight cube WC2 to generate a result. Adder AD3 then adds the result to the temporary value stored in register SR3 to generate a temporary value that is stored in temporary storage register SR4.

Circuit 220 continues as above, ending with multiplier MP144 multiplying the value stored in element 1,1 of 3×3 shift array SA144 within intermediate array SH144, and the weight value stored in element 1,1 of 3×3 weight array WR2,144 of weight cube WC2 to generate a result. Adder AD144 then adds the result to the temporary value stored in register SR144 to generate a value that is stored in temporary register SR1 as an element 1,1 value.

Circuit 220 continues as above, ending, as shown in FIG. 4I, with multiplier MP144 multiplying the value of element 3,3 of intermediate array SH144 and the weight value W2,144 of 3×3 weight array 2,144 to generate a result. Adder AD144 then adds the result to the temporary value stored in register SR144 to generate a final value that is stored in element 1,1 of transformed array SF2 of the transformed cube.

Circuit 220 continues as above until, as shown in FIG. 4J, the value of element 3,3 of transformed array SF2 of the transformed cube has been determined and stored. Once the value of element 3,3 of transformed array SF2 has been determined and stored, circuit 210 continues as above until the values for all of the elements of all of the remaining transformed arrays SF3-SF144 have been determined and stored. The result is a transformed cube with 144-3×3 arrays.

In the present invention, the weight cubes WC1-WC144 are dense weight cubes. As noted above, a dense cube is a cube where less than one-half of the total number of elements in the feature maps are zero. In an alternate embodiment, the weight cubes can be sparse cubes as well. (Padding can change the 3×3 transformed arrays to 5×5 transformed arrays to maintain a 5×5 size). The transformed arrays SF are illustrated as 3×3 arrays rather than 56×56 arrays for simplicity. Using 56×56 arrays in lieu of 3×3 arrays generates a 56×56×144 transformed cube 224 as shown in FIG. 2.

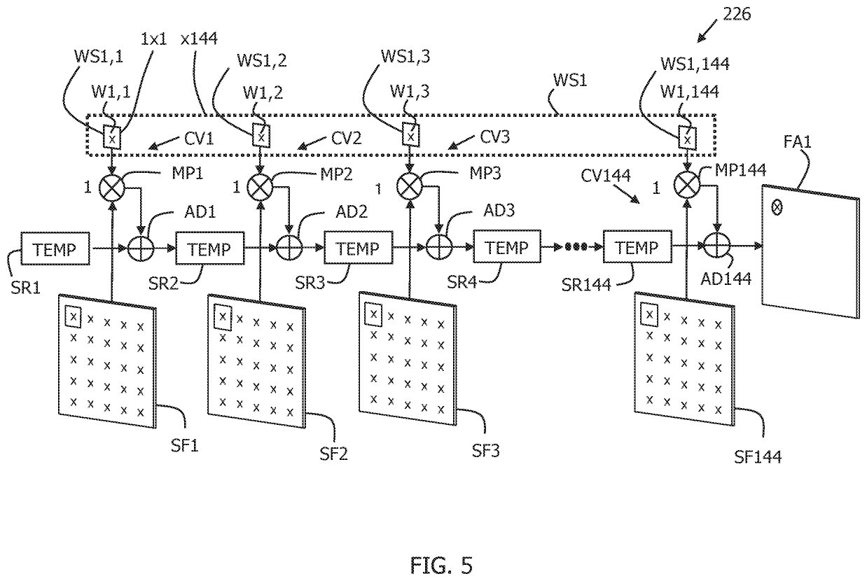

FIG. 5 shows a block diagram that illustrates an example of output circuit 226 in accordance with the present invention. Output circuit 226 is similar to input circuit 210 and, as a result, utilizes the same reference numerals to designate the structures that are common to both circuits. As shown in FIG. 5, output circuit 226 differs from input circuit 210 in that output circuit 226 utilizes 144—1×1 sparse output weight cubes WS instead of the 144—1×1 sparse input weight cubes CB utilized by input circuit 210. In addition, output circuit 226 inputs the transformed arrays SF of a transformed cube, such as transformed cube 224, instead of the channel arrays CH of the input cube.

Using the sparse output weight cubes WS and transformed arrays SF of a transformed cube, such as transformed cube 224 of FIG. 2, output circuit 226 operates the same as input circuit 210 to generate a feature cube, such as feature cube 232, that has 144 feature map arrays FA where the feature map arrays FA in a feature cube are the layers of the feature cube.

The weights required for the sparse output weight cubes and arrays can be represented in an output weight table as shown in TABLE 2, which illustrates 144—1×1×144 sparse output weight cubes.

TABLE 2

| | Input SF1 | Input SF2 | Input SF3 | Input SF144 |
|---|---|---|---|---|
| Out Wt Cube WS1 | W1, 1 | W1, 2 | W1, 3 | W1, 144 |
| Out Wt Cube WS2 | W2, 1 | W2, 2 | W2, 3 | W2, 144 |
| Out Wt Cube WS3 | W3, 1 | W3, 2 | W3, 3 | W3, 144 |
| Out Wt Cube WS144 | W144, 1 | W144, 2 | W144, 3 | W144, 144 |

In the present invention, the output weight table in TABLE 2 is a sparse table, which is a table where the number of zero entries is more than one-half of the total entries in the table.

One advantage of the present invention is that sparse weight cubes with the weights defined by the sparse tables of TABLE 1 and TABLE 2 allow output circuit 226 to output a 56×56×144 feature cube that is substantially more accurate than the 56×56×24 feature cube conventionally output by a projection bottleneck circuit while at the same time, due to the sparsity, consuming approximately the same number of floating point operations per second (FLOPS).

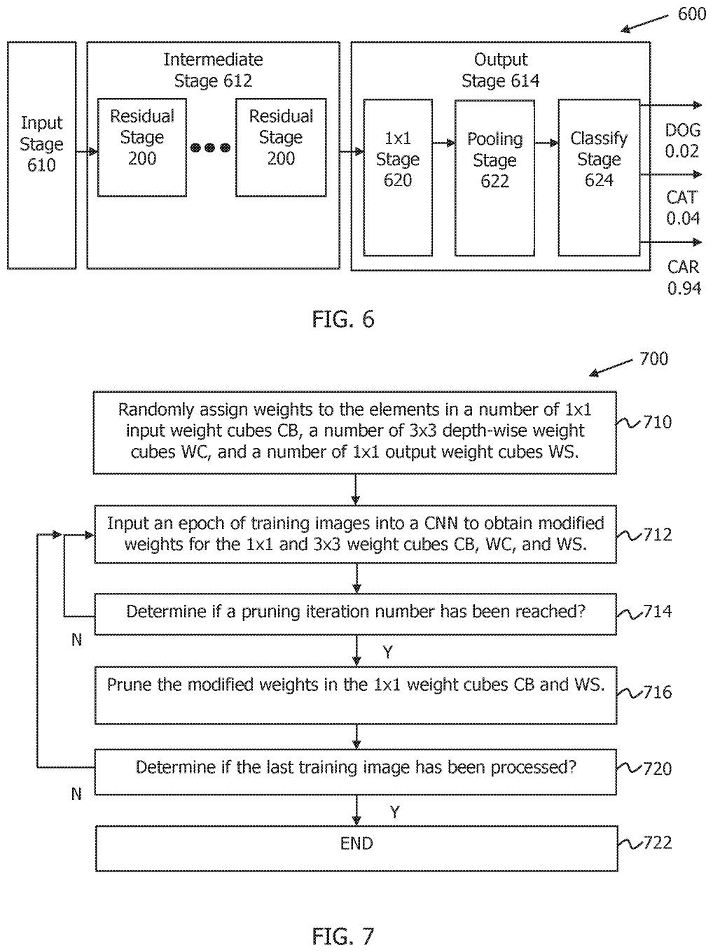

FIG. 6 shows a block diagram that illustrates an example of a CNN 600 in accordance with the present invention. As shown in FIG. 6, CNN 600 includes an input stage 610, and an intermediate stage 612 that is coupled to the input stage 610. Intermediate stage 612 includes a number of serially connected residual stages 200.

In addition, CNN 600 further includes an output stage 614 that is coupled to intermediate stage 612. Output stage 614 includes a regular 1×1 convolutional circuit 620 that is coupled to the last residual circuit 200 of intermediate stage 612, a global average pooling circuit 622 that is coupled to 1×1 convolutional circuit 620, and a fully-connected classification circuit 624 that is coupled to pooling circuit 622 to output one or more labeled probabilities. For example, classification circuit 624 can generate the following labels and probabilities that identify an object in an image input to CNN 600: a dog with a 0.02 probability, a cat with a 0.04 probability, and a car with a 0.94 probability. Classification circuit 624 can optionally output the label with a highest probability as a detected image.

The sparse weight cubes CB and WS are formed during training. FIG. 7 shows a flow chart that illustrates an example of a method 700 of forming a sparse weight cube in accordance with the present invention. As shown in FIG. 7, method 700 begins at 710 by randomly assigning weights to the elements in the 1×1 input weight arrays in the sparse input weight cubes, the 3×3 depth-wise dense weight arrays, and the 1×1 output weight arrays in the sparse output weight cubes.

Following this, method 700 moves to 712 to input an epoch of training images, such as one million training images, into a CNN, such as CNN 600, to obtain modified weights for the 1×1 and 3×3 weight cubes CB, WC, and WS. For example, each of the training images can be forward propagated completely through CNN 600 to obtain a number of input and intermediate values, and then backward propagated using the input and intermediate values to generate weight gradients for each weight array in each weight cube CB, WC, and WS. The weight gradients are then used to update the values in the 1×1 and 3×3 weight cubes CB, WC, and WS to obtain modified weights.

Method 700 next moves to 714 to determine if a pruning iteration number, such as 100, has been reached. If the pruning iteration number has not been reached, method 700 returns to 712 to process another training image. If the pruning iteration number has been reached, method 700 moves to 716 to prune the modified weights in the 1×1 sparse weight cubes CB and WS.

Pruning, which is conventionally performed, sets a number of the entries in the 1×1 sparse weight cubes CB and WS to zero. For example, if the pruning iteration number is set to one, the modified weights in the 1×1 sparse weight cubes CB and WS are pruned after every epoch of training images. If the pruning cycle number is set to two, the modified weights in the 1×1 sparse weight cubes CB and WS are pruned after every two epochs of training images.

Once the sparse weight cubes have been pruned, method 700 moves to 720 to determine if the last training image has been processed. If not, method 700 returns to 712 to process another training image. If so, method 700 moves to 722 to end.

Although the invention has been described in terms of a CNN stage in a neural network, the mechanism is not limited to natural language and vision models. The same mechanism can be applied to other types of models. Similar patterns, but different block structures are used.

Reference has now been made in detail to the various embodiments of the present disclosure, examples of which are illustrated in the accompanying drawings. While described in conjunction with the various embodiments, it will be understood that these various embodiments are not intended to limit the present disclosure. On the contrary, the present disclosure is intended to cover alternatives, modifications and equivalents, which may be included within the scope of the present disclosure as construed according to the claims.

Furthermore, in the preceding detailed description of various embodiments of the present disclosure, numerous specific details are set forth in order to provide a thorough understanding of the present disclosure. However, it will be recognized by one of ordinary skill in the art that the present disclosure may be practiced without these specific details or with equivalents thereof. In other instances, well-known methods, procedures, components, and circuits have not been described in detail so as not to unnecessarily obscure aspects of various embodiments of the present disclosure.

It is noted that although a method may be depicted herein as a sequence of numbered operations for clarity, the numbering does not necessarily dictate the order of the operations. It should be understood that some of the operations may be skipped, performed in parallel, or performed without the requirement of maintaining a strict order of sequence.

The drawings showing various embodiments in accordance with the present disclosure are semi-diagrammatic and not to scale and, particularly, some of the dimensions are for the clarity of presentation and are shown exaggerated in the drawing Figures. Similarly, although the views in the drawings for the ease of description generally show similar orientations, this depiction in the Figures is arbitrary for the most part. Generally, the various embodiments in accordance with the present disclosure can be operated in any orientation.

Some portions of the detailed descriptions are presented in terms of procedures, logic blocks, processing, and other symbolic representations of operations on data bits within a computer memory. These descriptions and representations are used by those skilled in the data processing arts to effectively convey the substance of their work to others skilled in the art.

In the present disclosure, a procedure, logic block, process, or the like, is conceived to be a self-consistent sequence of operations or instructions leading to a desired result. The operations are those utilizing physical manipulations of physical quantities. Usually, although not necessarily, these quantities take the form of electrical or magnetic signals capable of being stored, transferred, combined, compared, and otherwise manipulated in a computing system. It has proven convenient at times, principally for reasons of common usage, to refer to these signals as transactions, bits, values, elements, symbols, characters, samples, pixels, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present disclosure, discussions utilizing terms such as “generating,” “determining,” “assigning,” “aggregating,” “utilizing,” “virtualizing,” “processing,” “accessing,” “executing,” “storing,” or the like, refer to the action and processes of a computer system, or similar electronic computing device or processor.

The computing system, or similar electronic computing device or processor manipulates and transforms data represented as physical (electronic) quantities within the computer system memories, registers, other such information storage, and/or other computer readable media into other data similarly represented as physical quantities within the computer system memories or registers or other such information storage, transmission or display devices.

The technical solutions in the embodiments of the present application have been clearly and completely described in the prior sections with reference to the drawings of the embodiments of the present application. It should be noted that the terms “first,” “second,” and the like in the description and claims of the present invention and in the above drawings are used to distinguish similar objects and are not necessarily used to describe a specific sequence or order. It should be understood that these numbers may be interchanged where appropriate so that the embodiments of the present invention described herein can be implemented in orders other than those illustrated or described herein.

The functions described in the operations and methods of the present embodiment can be implemented in logic or with software and a processing unit. If implemented in the form of a software functional unit and sold or used as a standalone product, can be stored in a computing device readable storage medium. Based on such understanding, a portion of the embodiments of the present application that contributes to the prior art or a portion of the technical solution may be embodied in the form of a software product stored in a storage medium, including a plurality of instructions for causing a computing device (which may be a personal computer, a server, a mobile computing device, or a network device, and so on) to perform all or part of the steps of the methods described in various embodiments of the present application. The foregoing storage medium includes: a USB drive, a portable hard disk, a read-only memory (ROM), a random-access memory (RAM), a magnetic disk, an optical disk, and the like, which can store program code.

The various embodiments in the specification of the present application are described in a progressive manner, and each embodiment focuses on its difference from other embodiments, and the same or similar parts between the various embodiments may be referred to another case. The described embodiments are only a part of the embodiments, rather than all of the embodiments of the present application. All other embodiments obtained by a person of ordinary skill in the art based on the embodiments of the present application without departing from the inventive skills are within the scope of the present application.

The above description of the disclosed embodiments enables a person skilled in the art to make or use the present application. Various modifications to these embodiments are obvious to a person skilled in the art, and the general principles defined herein may be implemented in other embodiments without departing from the spirit or scope of the present application. Therefore, the present application is not limited to the embodiments shown herein, but the broadest scope consistent with the principles and novel features disclosed herein.

What is claimed is:

1. A computing processor device which may include a neural network module, comprising:
an input circuit to receive an input object that has a dense array with rows and columns of elements that each store a value, the input circuit to filter the input object with a first weight object that has a sparse array with rows and columns of elements to generate a first intermediate object;
an intermediate circuit coupled to the input circuit, the intermediate circuit to transform the first intermediate object to generate a second intermediate object; and
an output circuit to filter the second intermediate object with a second weight object that has a sparse array with rows and columns of elements to generate an output object.

2. The device of claim 1, wherein the dense array of the input object has a size of (M, P*K) where M is the height of the array of the input object, K is the width of the array of the input object, and P is a constant.

3. The device of claim 2, wherein the array of the first sparse weight object has a size of (P*K, P*K).

4. The device of claim 1 wherein the input object has a plurality of arrays that each has rows and columns of elements that each store a value.

5. The device of claim 4 wherein the first weight object has a plurality of arrays that each has rows and columns of elements that each store a value.

6. The device of claim 5 wherein the input object and the output object have matching sizes.

7. The device of claim 4 wherein the first weight object includes a plurality of 1×1 arrays.

8. A method of operating an artificial neural network, the method comprising:
receiving an input object that has a dense array with rows and columns of elements that each store a value, and filtering the input object with a first weight object that has a sparse array with rows and columns of elements to generate a first intermediate object;
transforming the first intermediate object to generate a second intermediate object; and
filtering the second intermediate object with a second weight object that has a sparse array with rows and columns of elements to generate an output object.

9. The method of claim 8, wherein the array of the input object has a size of (M, P*K) where M is the height of the array of the input object, K is the width of the array of the input object, and P is a constant.

10. The method of claim 9, wherein the array of the first weight object has a size of (P*K, P*K).

11. The method of claim 10 wherein the input object and the output object have matching sizes.

12. The method of claim 8 wherein the input object has a plurality of arrays that each has rows and columns of elements that each store a value.

13. The method of claim 12 wherein the first weight object has a plurality of arrays that each has rows and columns of elements that each store a value.

14. The method of claim 8 wherein the first weight object includes a plurality of 1×1 arrays.

15. A non-transitory computer-readable storage medium having embedded therein program instructions, which when executed by a processor causes the processor to execute a method of operating an artificial neural network, the method comprising:
receiving an input object that has a dense array with rows and columns of elements that each store a value, and filtering the input object with a first weight object that has a sparse array with rows and columns of elements to generate a first intermediate object;
transforming the first intermediate object to generate a second intermediate object; and
filtering the second intermediate object with a second weight object that has a sparse array with rows and columns of elements to generate an output object.

16. The medium of claim 15, wherein the array of the input object has a size of (M, P*K) where M is the height of the array of the input object, K is the width of the array of the input object, and P is a constant.

17. The medium of claim 16, wherein the array of the first weight object has a size of (P*K, P*K).

18. The medium of claim 17 wherein the input object and the output object have matching sizes.

19. The medium of claim 15 wherein the input object has a plurality of arrays that each has rows and columns of elements that each store a value.

20. The medium of claim 19 wherein the first weight object has a plurality of arrays that each has rows and columns of elements that each store a value.
